(19) United States
(12) Patent Application Publication
(10) Pub. No.: US 2019/0103501 A1
(43) Pub. Date: Apr. 4, 2019

(54) LIGHT-RECEIVING DEVICE, IMAGING UNIT, AND ELECTRONIC APPARATUS

(71) Applicant: SONY CORPORATION, Tokyo (JP)

(72) Inventors: Takahiro IGARASHI, Kanagawa (JP); Takahiro SONODA, Kagoshima (JP); Atsushi SUZUKI, Kanagawa (JP); Shinya YAMAKAWA, Kanagawa (JP); Hiroshi YUMOTO, Kagoshima (JP); Izuho HATADA, Kanagawa (JP); Takeshi KODAMA, Kanagawa (JP); Kiwamu ADACHI, Kanagawa (JP); Katsuji MATSUMOTO, Kanagawa (JP)

(73) Assignee: SONY CORPORATION, Tokyo (JP)

(21) Appl. No.: 16/087,189

(22) PCT Filed: Feb. 15, 2017
(86) PCT No.: PCT/JP2017/005472

§ 371 Date: Sep. 21, 2018

(30) Foreign Application Priority Data
Mar. 30, 2016 (JP) 2016-067646

(51) Int. Cl. H01L 31/06; H01L 31/0224; H04N 5/3745; H01L 27/146

(52) U.S. Cl. CPC H01L 31/06; H01L 31/022425; H01L 27/14643; H01L 27/14605; H01L 27/14636; H04N 5/37455

(57) ABSTRACT

A light-receiving device of an embodiment of the present disclosure includes, on a first principal surface of a semiconductor layer, a pixel region that includes a plurality of light-receiving pixels each receiving light incident from side of a second principal surface of the semiconductor layer. The light-receiving device further includes, throughout a gap between the second principal surface and the pixel region, a low-impurity region having a relatively lower impurity concentration than the pixel region. The light-receiving pixels each include one or a plurality of photoelectric current extraction regions each including, on the first principal surface, an anode region and a cathode region, and a circuit region that is electrically coupled to each of the cathode regions and is electrically separated from the impurity region.

### TECHNICAL FIELD

The present disclosure relates to a light-receiving device, an imaging unit, and an electronic apparatus.

### BACKGROUND ART

Various imaging units incorporating a photoelectric conversion region in each pixel (a light-receiving pixel) have been proposed. For example, PTL 1 gives an example of a backside illumination type imaging unit as an example of such an imaging unit including the photoelectric conversion region.

### CITATION LIST

### Patent Literature

PTL 1: Japanese Unexamined Patent Application Publication No. 2014-192348

### SUMMARY OF THE INVENTION

Such an imaging unit is constantly requested to have improved sensitivity. To address this, it is conceivable, for example, to remove a pixel circuit from a light-receiving surface and to provide a dedicated substrate only for a pixel circuit behind a pixel substrate having the light-receiving surface. In a case where such a configuration is adopted, it is possible to increase a rate of a photoelectric conversion element in the light-receiving surface, thus making it possible to improve the sensitivity. However, there has been an issue in which the provision of the dedicated substrate only for the pixel circuit results in significant increase in manufacturing costs. It is desirable to provide a light-receiving device, an imaging unit, and an electronic apparatus that make it possible to suppress significant increase in manufacturing costs while improving sensitivity.

A light-receiving device of an embodiment of the present disclosure includes a pixel region provided on a first principal surface of a semiconductor layer that includes the first principal surface, a second principal surface, and an end surface. The pixel region includes a plurality of light-receiving pixels each receiving light incident from side of the second principal surface. The second principal surface faces the first principal surface. The light-receiving device further includes a low-impurity region provided throughout a gap between the second principal surface and the pixel region. The low-impurity region has a relatively lower impurity concentration than the pixel region. The light-receiving pixels each include one or a plurality of photoelectric current extraction regions each including, on the first principal surface, an anode region and a cathode region, and a circuit region that is electrically coupled to each of the cathode regions and is electrically separated from the impurity region.

An imaging unit of an embodiment of the present disclosure includes a wiring substrate, and a plurality of light-receiving devices mounted in matrix on the wiring substrate. The plurality of light-receiving devices each include a pixel region provided on a first principal surface of a semiconductor layer that includes the first principal surface, a second principal surface, and an end surface. The pixel region includes a plurality of light-receiving pixels each receiving light incident from side of the second principal surface. The first principal surface is closer to the wiring substrate. The second principal surface faces the first principal surface. The plurality of light-receiving devices each further include a low-impurity region provided throughout a gap between the second principal surface and the pixel region. The low-impurity region has a relatively lower impurity concentration than the pixel region. The light-receiving pixels each include one or a plurality of photoelectric current extraction regions each including, on the first principal surface, an anode region and a cathode region, and a circuit region that is electrically coupled to each of the cathode regions and is electrically separated from the impurity region.

An electronic apparatus of an embodiment of the present disclosure includes an imaging unit and a processing unit that processes image data obtained by the imaging unit. The imaging unit provided in the electronic apparatus includes the same elements as those of the imaging unit.

The light-receiving device, the imaging unit, and the electronic apparatus of the embodiments of the present disclosure are each provided, in the semiconductor layer, with the pixel region on a surface (the first principal surface) on side opposite to the light-receiving surface (the second principal surface). Further, the low-impurity region is provided throughout a gap between the light-receiving surface and the pixel region. In this manner, in the present disclosure, the low-impurity region is formed throughout the light-receiving surface, and there is no structure (specifically, a pixel circuit, a light-shielding layer, a device separation layer, etc.) that blocks light reception in the light-receiving surface. Accordingly, the light incident from side of the light-receiving surface enters the low-impurity region that spreads throughout the light-receiving surface, without being vignetted by the structure that blocks light reception, and the light having entered the low-impurity region is converted into a photoelectric current. Further, the provision of the pixel region in the semiconductor layer makes it unnecessary to provide a dedicated substrate only for the pixel circuit.

According to the light-receiving device, the imaging unit, and the electronic apparatus of the embodiments of the present disclosure, the semiconductor layer is provided with the pixel region, and light incident from the side of the light-receiving surface enters the low-impurity region that spreads throughout the light-receiving surface, without being vignetted by the structure that blocks light reception. This makes it possible to suppress increase in manufacturing costs while improving sensitivity. It is to be noted that the effects described here are not necessarily limitative, and may have any of the effects described in the present specification.

### BRIEF DESCRIPTION OF DRAWINGS

FIG. 1 illustrates an example of a cross-sectional configuration of a light-receiving device according to a first embodiment of the present disclosure.

FIG. 2 illustrates an example of a planar configuration of a second principal surface in the light-receiving device of FIG. 1.

FIG. 3 illustrates an example of a planar configuration of a first principal surface in the light-receiving device of FIG. 1.

FIG. 4 illustrates an example of a carrier polarity in each component inside the light-receiving device of FIG. 1.

FIG. 5 illustrates an example of a circuit ion in the light-receiving device of FIG. 1.

FIG. 6 illustrates an example of a planar configuration of the first principal surface in the light-receiving device of FIG. 1.

FIG. 7 illustrates an example of a planar configuration of the first principal surface in the light-receiving device of FIG. 1.

FIG. 8 illustrates an example of a planar configuration of the first principal surface in the light-receiving device of FIG. 1.

FIG. 9 illustrates an example of a planar configuration of the first principal surface in the light-receiving device of FIG. 1.

FIG. 10 illustrates an example of a schematic configuration of an imaging unit according to a second embodiment of the present disclosure.

FIG. 11 illustrates an example of a cross-sectional configuration of an imaging section of FIG. 10.

FIG. 12 illustrates an example of a schematic configuration of an imaging system according to a third embodiment of the present disclosure.

### MODES FOR CARRYING OUT THE INVENTION

In the following, embodiments for carrying out the present disclosure are described in detail with reference to drawings. It is to be noted that the description is given in the following order.
1. First Embodiment (Light-Receiving Device)
2. Modification Example of First Embodiment (Light-Receiving Device)
3. Second Embodiment (Imaging Unit)
4. Third Embodiment (Imaging System)
5. Modification Example of Third Embodiment (imaging System)

### 1. First Embodiment

### [Configuration]

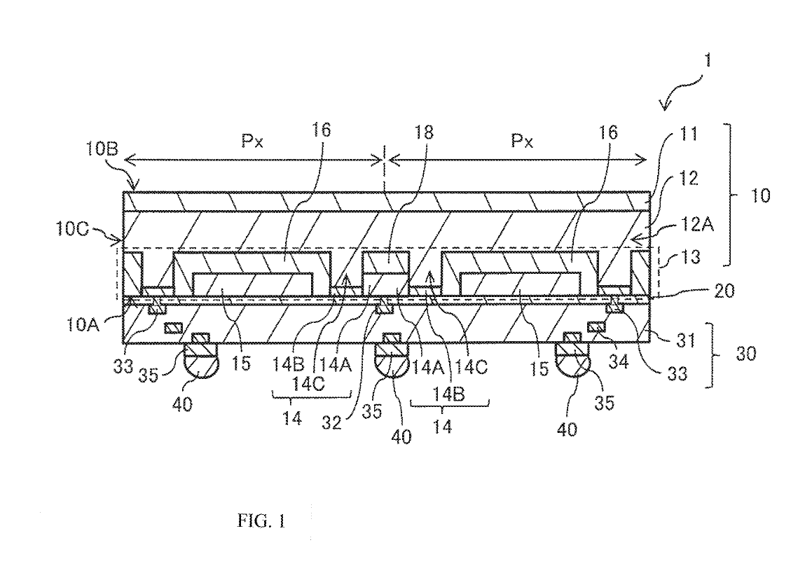

Description is given of a light-receiving device 1 according to a first embodiment of the present disclosure. FIG. 1 illustrates an example of a cross-sectional configuration of the light-receiving device 1. The light-receiving device 1 receives light incident on a second principal surface 10B as a top surface. The light-receiving device 1 has a back surface that faces the second principal surface 10B. The light-receiving device 1 is a chip-shaped device provided with a plurality of solder bumps 40 on the back surface. In other words, the light-receiving device 1 includes, on the back surface, a mechanism that allows for electrical coupling to the outside; the mechanism is neither provided on the second principal surface 10B as the top surface, nor on a side surface. The light-receiving device 1 has a polygonal planar shape suitable for tiling, for example, a quadrangular shape, as viewed in a normal direction of the second principal surface 10B.

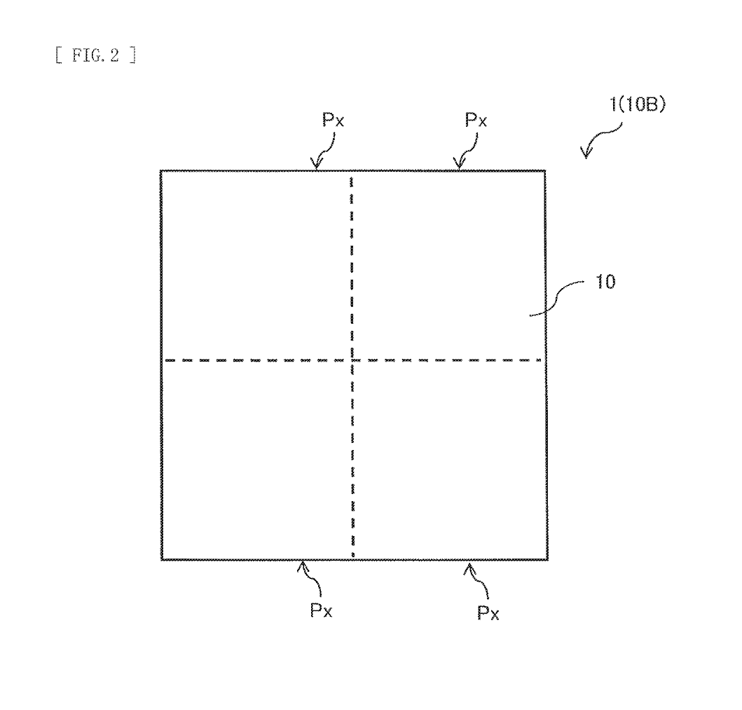

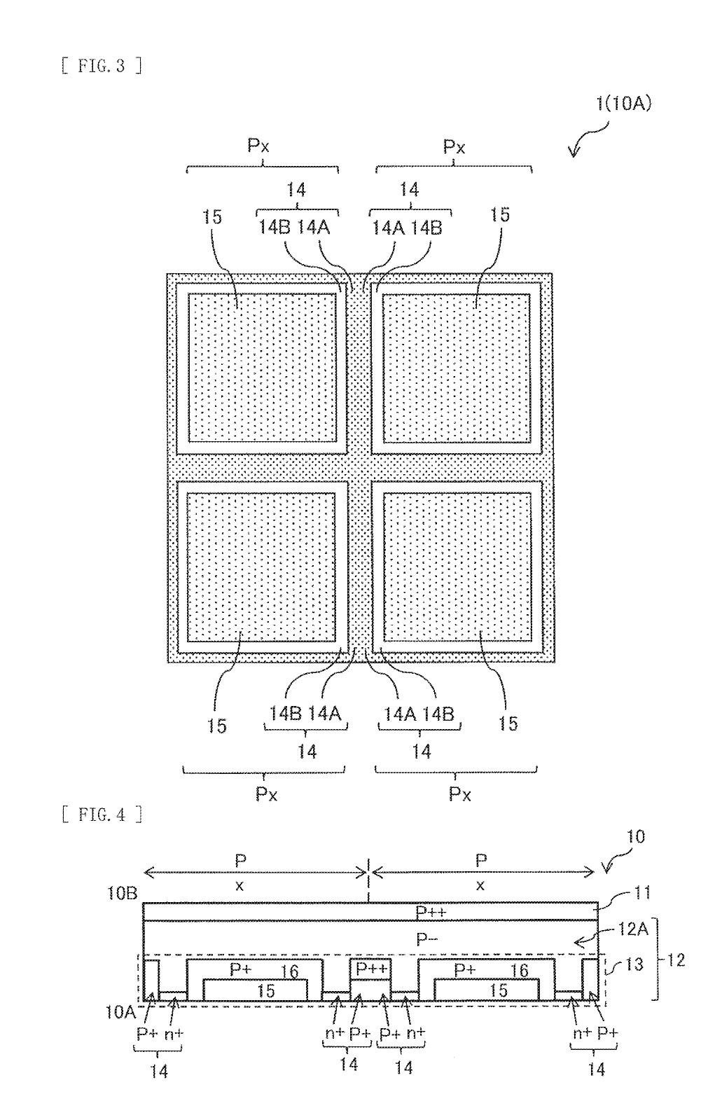

The light-receiving device 1 includes a semiconductor layer 10. The semiconductor layer 10 has a first principal surface 10A, the second principal surface 10B that faces the first principal surface 10A, and an end surface 10C. FIG. 2 illustrates an example of a planar configuration of the second principal surface 10B of the light-receiving device 1 of FIG. 1. FIG. 3 illustrates an example of a planar configuration of the first principal surface 10A of the light-receiving device 1 of FIG. 1. The first principal surface 10A is a surface on side opposite to the second principal surface 10B in the semiconductor layer 10, and forms an interface with an insulating layer 20 described later. The end surface 10C is a cut surface formed by means of dicing or dry etching, and is in contact with an outer edge of each of the first principal surface 10A and the second principal surface 10B. The light-receiving device 1 further includes the insulating layer 20, a wiring layer 30, and the plurality of solder bumps 40 on side of the first principal surface 10A of the semiconductor layer 10. The insulating layer 20 and the wiring layer 30 are each a layer formed, in a manufacturing process, on the first principal surface 10A as a base surface. The semiconductor layer 10 includes a semiconductor substrate 11 and an epitaxial growth layer.

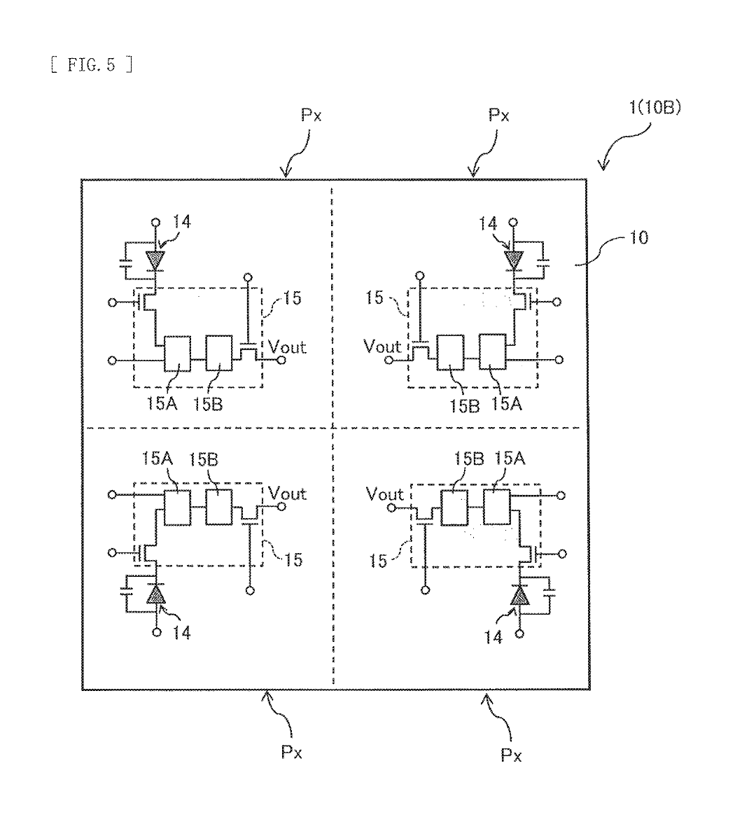

The semiconductor substrate 11 is a substrate that constitutes a surface of the second principal surface 10B, and is a portion of a forming substrate when forming the epitaxial growth layer 12 in the manufacturing process. The semiconductor substrate 11 is formed by a single crystal silicon, for example. The semiconductor substrate 11 is a substrate reduced in thickness by subjecting a substrate used for formation of the epitaxial growth layer 12 in the manufacturing process to etching such as chemical mechanical polishing (CMP) or to a grinder. The second principal surface 10B serves as a light-incident surface in the light-receiving device 1. Hence, the light-receiving device 1 is a backside illumination type light-receiving device. FIG. 1 illustrates a cross-section of the light-receiving device 1 to allow the second principal surface 10B as the back surface of the light-receiving device 1 to be the top surface. As illustrated in FIG. 4, for example, the semiconductor substrate 11 is configured by a p-type semiconductor having a relatively higher p-type impurity concentration than that of a pixel region 13 described later. In the present embodiment, the semiconductor substrate 11 is configured by the p-type semiconductor. The semiconductor substrate 11 may be omitted as necessary. In this case, the second principal surface 10B is preferably provided with an epitaxial growth layer doped with high-concentration impurities, or a layer doped with high-concentration impurities. In a case where the semiconductor substrate 11 is omitted, a surface, of the epitaxial growth layer 12, opposite to the first principal surface 10A serves as the second principal surface 10B.

The epitaxial growth layer 12 is a substrate that constitutes a surface of the first principal surface 10A. The epitaxial growth layer 12 is formed to be in contact with the semiconductor substrate 11. The epitaxial growth layer 12 is an epitaxial crystal growth layer formed on the semiconductor substrate 11 in the manufacturing process. The epitaxial growth layer 12 is formed by a single crystal silicon, for example.

The epitaxial growth layer 12 includes a pixel region 13 on the first principal surface 10A of the semiconductor layer 10. The pixel region 13 includes a plurality of light-receiving pixels Px that receive light incident from side of the second principal surface 10B. FIG. 1 exemplifies a case where the pixel region 13 includes four light-receiving pixels Px. The pixel region 13 may include five or more light-receiving pixels Px. The semiconductor substrate 11 and a low-impurity region 12A are provided between each of the light-receiving pixels Px and the second principal surface 10B, and thus light incident on the second principal surface 10B is not blocked by an element separation region or a light-shielding region until entering each of the light-receiving pixels Px.

The pixel region 13 includes a p-type impurity region and an n-type impurity region. The p-type impurity region is formed by diffusing high-concentration p-type impurities to the epitaxial growth layer 12. The n-type impurity region is formed by diffusing high-concentration n-type impurities to the epitaxial growth layer 12. A region, of the epitaxial growth layer 12, other than the pixel region 13 is configured by a p-type semiconductor having a relatively lower p-type impurity concentration than that of the p-type impurity region inside the pixel region 13. In the following, the region, of the epitaxial growth layer 12, other than the pixel region 13 is referred to as the low-impurity region 12A. The low-impurity region 12A is provided throughout a gap between the second principal surface 10B and the pixel region 13.

Each of the light-receiving pixels Px includes one or a plurality of photoelectric current extraction regions 14 and a circuit region 15 electrically coupled to the one or the plurality of photoelectric current extraction regions 14. FIG. 3 exemplifies a case where each of the light-receiving pixels Px includes one photoelectric current extraction region 14 and the circuit region 15 electrically coupled to the one photoelectric current extraction region 14.

The photoelectric current extraction region 14 is provided to extract a photoelectric current from a depletion region that generates a signal electric charge (photoelectric current) having an electric charge amount corresponding to a light amount of light (incident light) incident from the side of the second principal surface 10B. The photoelectric current extraction region 14 includes, on the first principal surface 10A, an anode region 14A and a cathode region 14B. The anode region 14A is configured by a semiconductor of the same electroconductive type as that of the low-impurity region 12A. The anode region 14A is configured by a p-type semiconductor having a relatively higher p-type impurity concentration than that of the low-impurity region 12A. The cathode region 14B is configured by a semiconductor of an electroconductive type different from that of the low-impurity region 12A. The anode region 14A and the cathode region 14B are in contact with each other on the first principal surface 10A, and constitute a pn type photodiode. Application of a voltage to the anode region 14A and the cathode region 14B forms a depletion region in the low-impurity region 12A. During a period when a voltage is applied to the anode region 14A and the cathode region 14B, in general, the depletion region spreads partially in the low-impurity region 12A. The depletion region is a region where almost no electrons or holes are present that are carriers. The depletion region converts light incident from the side of the second principal region 10B into a photoelectric current.

The cathode region 14B has a ring shape that surrounds the circuit region 15 on the first principal surface 10A. The anode region 14A is formed to surround the cathode region 14B and the circuit region 15 on the first principal surface 10A. The anode region 14A is in contact with an outer edge of the cathode region 14B on the first principal surface 10A. The photoelectric current extraction region 14 has a ring shape that surrounds the circuit region 15 n the first principal surface 10A. In each of the light-receiving pixels Px, the photoelectric current extraction region 14 is provided at an outer edge of each of the light-receiving pixels Px. The photoelectric current extraction region 14 provided at the outer edge of each of the light-receiving pixels Px corresponds to a specific example of a “first photoelectric current extraction region” of the present disclosure.

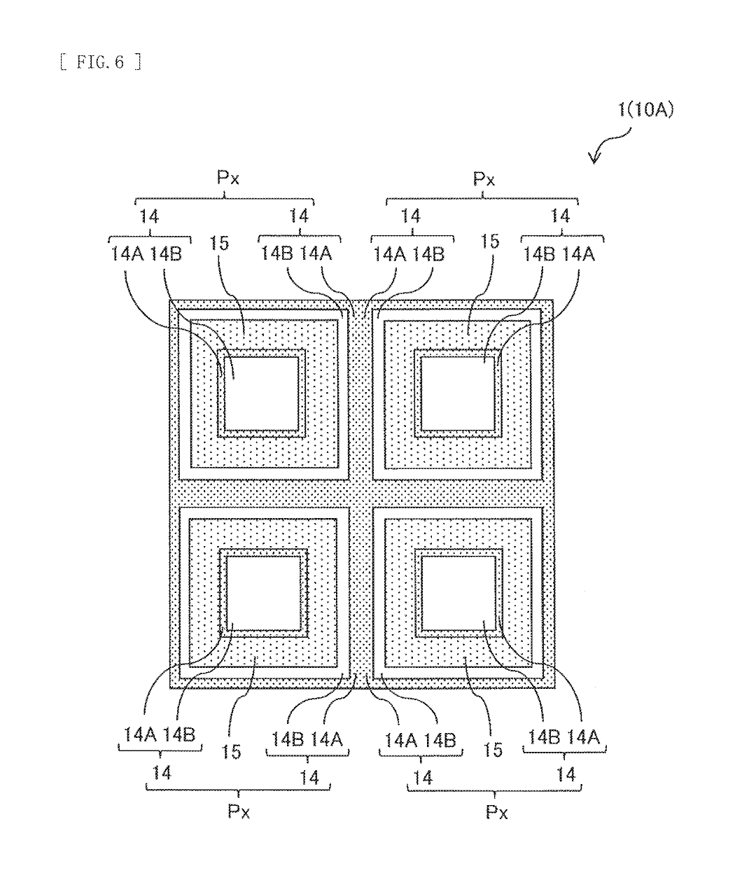

FIG. 5 illustrates an example of a circuit configuration of the light-receiving device 1 of FIG. 1. In each of the light-receiving pixels Px, the circuit region 15 includes at least a conversion circuit 15A, out of the conversion circuit 15A and a buffer circuit 15B coupled to an output of the conversion circuit 15A. The conversion circuit 15A converts a photoelectric current outputted from the one or the plurality of photoelectric current extraction regions 14 into a voltage signal. FIG. 5 exemplifies a case where the circuit region 15 includes the conversion circuit 15A and the buffer circuit 15B. The circuit region 15 outputs an output signal Vout through the conversion circuit 15A and the buffer circuit 15B. The circuit region 15 may include a switch element at an output end of the buffer circuit 15B. The circuit region 15 may include a circuit that reduces a noise included in the output signal Vout. In each of the light-receiving pixels Px, the circuit region 15 is formed on the first principal surface 10A. The photoelectric current extraction region 14 includes, on the first principal surface 10A, the anode region 14A and the cathode region 14B. In each of the light-receiving pixels Px, the anode region 14A and the cathode region 14B are formed on the first principal surface 10A. It is to be noted that one buffer circuit 15B may not be provided for each circuit region 15. In this case, however, for example, the buffer region 15B may be provided only in one circuit region 15 inside the light-receiving device 1, and the buffer circuit 15B may be shared by all of the light-receiving pixels Px inside the light-receiving device 1.

The pixel region 13 includes, other than the plurality of light-receiving pixels Px, a plurality of separation regions 16 and a plurality of separation regions 17. The plurality of separation regions 16 are provided for the respective light-receiving pixels Px. Each of the separation regions 16 is configured to electrically separate the low-impurity region 12A and the circuit region 15 from each other in a thickness direction and in an in-plane direction of the epitaxial growth layer 12. Each of the separation regions 16 is formed between the low-impurity region 12A and the circuit region 15 in the thickness direction and in the in-plane direction of the epitaxial growth layer 12. Each of the separation regions 16 is configured by an impurity region that contains impurities of the same electroconductive type as that of the low-impurity region 12A at a higher concentration than that of the low-impurity region 12A. The separation region 16 corresponds to a specific example of a “separation region” of the present disclosure.

The pixel region 13 further includes a plurality of separation regions 18. The plurality of separation regions 18 are each configured to electrically separate two of the light-receiving pixels Px adjacent to each other in the in-plane direction of the epitaxial growth layer 12, from each other. Each of the separation regions 18 is formed between the two light-receiving pixels Px adjacent to each other in the pixel region 13. Each of the separation regions 18 is formed, for example, between the anode region 14A and the low-impurity region 12A in the thickness direction of the epitaxial growth layer 12. Each of the separation regions 18 is configured by an impurity region that contains impurities of the same electroconductive type as that of the low-impurity region 12A at a concentration equivalent to that of the anode region 14A.

The light-receiving device 1 further includes the insulating layer 20 in contact with the first principal surface 10A of the semiconductor layer 10, the wiring layer 30 in contact with the insulating layer 20, and the plurality of solder bumps 40. The plurality of solder bumps 40 are formed on a surface of the wiring layer 30, and are provided for respective wiring lines 34 (described later) inside the wiring layer 30.

The insulating layer 20 is a layer with an insulation property in contact with the first principal surface 10A. For example, the insulating layer 20 is formed by, in the manufacturing process, forming, for example, an oxide film on a surface of the epitaxial growth layer 12 before formation of the pixel region 13. The insulating layer 20 is provided with an opening at a location that faces the anode region 14A or the cathode region 14B. An anode electrode 32 described later is electrically coupled to the anode region 14A via the opening of the insulating layer 20. A cathode electrode 33 described later is electrically coupled to the cathode region 14B via the opening of the insulating layer 20.

The wiring layer 30 is provided on the side of the first principal surface 10A in terms of a position-1 relationship with the semiconductor layer 10. The wiring layer 30 includes the plurality of anode electrodes 32, the plurality of cathode electrodes 33, the plurality of wiring lines 34, an interlayer insulating film 31, and a plurality of electrodes 35. Each anode electrode 32, each cathode electrode 33, and each wiring line 34 are embedded in the interlayer insulating film 31. Each electrode 35 is formed on a surface of the interlayer insulating film 31, and serves as a pad electrode on which each solder bump 40 is to be mounted. As described above, each anode electrode 32 is electrically coupled to the anode region 14A via the opening of the insulating layer 20. As described above, each cathode electrode 33 is electrically coupled to the cathode electrode 33 via the opening of the insulating layer 20.

A certain wiring line 34 electrically couples the anode electrode 32 and the solder bump 40 to each other. Another wiring line 34 electrically couples one input terminal of the circuit region 15 and the cathode region 14B to each other. Another wiring line 34 electrically couples another input terminal of the circuit region 15 and the solder bump 40 to each other. Another wiring line 34 electrically couples an output terminal of the circuit region 15 and the solder bump 40 to each other.

### [Manufacturing Method]

Description is given next of an example of a method of manufacturing the light-receiving device 1. A semiconductor substrate is first prepared that is provided with the epitaxial growth layer 12 on the semiconductor substrate 11. Next, an oxide film is formed to form the insulating layer 20. Next, the separation regions 16 and 18 and the anode region 14A are formed. Specifically, a p-type ion implantation is performed to thereby form the plurality of island-shaped separation regions 16, the grid-shaped separation region 18, and the anode region 14A.

Next, the cathode region 14B is formed. Specifically, an n-type ion implantation is performed to thereby form the plurality of ring-shaped cathode regions 14B to each surround the separation region 16 and to be in contact with an inner edge of the anode region 14A. In this manner, in each of the light-receiving pixels Px, one ring-shaped photoelectric current extraction region 14 is formed. Next, the circuit region 15 is formed in a region, of the epitaxial growth layer 12, surrounded by each of the separation regions 17.

Next, a metal wiring line is formed. Specifically, for example, the anode electrode 32 and the plurality of cathode electrodes 33 are formed on the insulating layer 20. At this time, the plurality of cathode electrodes 33 are assigned to the respective cathode regions 14B on a one-to-one basis. Next, the interlayer insulating film 31, the plurality of wiring lines 34, and the plurality of electrodes 35 are formed. In this manner, the wiring layer 30 is formed on the insulating layer 20.

Next, in a case where the light-receiving device 1 is used as the backside illumination type light-receiving device, the semiconductor substrate 11 is rescued in thickness. Next, device separation is performed. Specifically, for example, a support substrate is joined to the semiconductor substrate 11, and a predetermined location of the semiconductor substrate 11 is subjected to dicing, dry etching, or the like to thereby separate the semiconductor substrate 11 into pieces each having a predetermined size. In this manner, the plurality of light-receiving devices 1 each having the end surface 10C are formed. Next, the solder bump 40 is formed on each of the electrodes 35. In this manner, the light-receiving device 1 of FIG. 1 is manufactured.

### [Operation]

Description is given next of an example of an operation of the light-receiving device 1. Visible light is incident on the second principal surface 10B of the light-receiving device 1. At this time, a reverse bias voltage is applied to the photoelectric current extraction region 14. The light incident on the second principal surface 10B is converted into a signal electric charge (photoelectric current) having an electric charge amount corresponding (proportional) to a light amount of the incident light. The signal electric charge (photoelectric current) extracted inside the photoelectric current extraction region 14 is converted into the output signal Vout via the circuit region 15, and is outputted to the outside via the wiring layer 30 and the solder bump 40.

### [Effects]

Description is given next of effects of the light-receiving device 1. The light-receiving device 1 is provided with the pixel region Px in the semiconductor layer 10 on a surface (the first principal surface 10A) on side opposite to the light-receiving surface (the second principal surface 10B). Further, a low-impurity region (the semiconductor substrate 11 and the low-impurity region 12A) is provided throughout a gap between the second principal surface 10B and the pixel region Px. In the present embodiment, the low-impurity region (the semiconductor substrate 11 and the low-impurity region 12A) is formed in this manner throughout the second principal surface 10B, and no structure (specifically, a pixel circuit, a light-shielding layer, a device separation layer, etc) that blocks light reception is present on the second principal surface 10B. Accordingly, the light incident from the side of the second principal surface 10B enters the low-impurity region (the semiconductor substrate 11 and the low-impurity region 12A) that spreads throughout the second principal surface 10B, without being vignetted by the structure that blocks light reception. Thereafter, the light incident on the low-impurity region is converted into a photoelectric current in the depletion region that is formed in the low-impurity region (the semiconductor substrate 11 and the low-impurity region 12A) by means of application of a voltage to each of the photoelectric current extraction regions 14. Further, the provision of the pixel region 13 in the semiconductor layer 10 makes it unnecessary to provide a dedicated substrate only for the pixel region 13. Hence, it is possible to suppress increase in manufacturing costs while improving sensitivity.

In the present embodiment, each of the separation regions 16 electrically separates the low-impurity region 12A and the circuit region 15 from each other. This suppresses flow of the photoelectric current into the circuit region 15 even in a case where the circuit region 15, the photoelectric current extraction region 14, and the like are formed in the common semiconductor layer 10. As a result, it becomes possible to improve sensitivity.

In the present embodiment, the separation region 16 is configured by the impurity region that contains impurities of the same electroconductive type as that of the low-impurity region 12A at a higher concentration than that of the low-impurity region 12A. When forming the anode region 14A and the separation region 18 in the manufacturing process, it is possible for the separation region 16 to be formed together. Hence, it becomes possible to suppress increase in manufacturing costs because it is unnecessary to add a process step for formation of the separation region 16.

In the present embodiment, the photoelectric current extraction region 14 is provided at the outer edge of the light-receiving pixel Px, and has a ring shape that surrounds the circuit region 15 on the first principal surface 10A. The photoelectric current extraction region 14 having a ring shape makes it possible to extract, near the second principal surface 10B, a photoelectric charge throughout the surface with broadened potential. This makes it possible to secure sufficient area as the circuit region 15 while securing high light-receiving sensitivity.

In the present embodiment, the circuit region 15 includes at least the conversion circuit 15A, out of the conversion circuit 15A and the amplifier circuit 15B. This makes it possible to reduce a distance between the photoelectric current extraction region 14 and the conversion circuit 15A, thus making the circuit region 15 less likely to be influenced by a noise. As a result, it becomes possible to improve S/N.

In the present embodiment, the wiring layer 30 including the plurality of wiring lines 34 electrically coupled to each of the receiving pixels Px is provided on the side of the first principal surface 10A. Further, the plurality of solder bumps 40 electrically coupled to the plurality of wiring lines 34 are provided on the surface of the wiring layer 30. This allows for soldering mounting, thus making it possible suppress increase in manufacturing costs while improving S/N.

Further, the provision of the photoelectric current extraction region 14 on the first principal surface 10A of the light-receiving device 1 allows for soldering mounting, thus making it possible to narrow a gap between the light-receiving devices 1 that are adjacent to each other. This makes it possible to lay the plurality of light-receiving devices 1 on a wiring substrate or the like almost without any clearance. For example, in a case of a so-called surface-type photodiode having a cathode surface as a light-receiving surface, when the photodiode is provided on the light-receiving surface, it is necessary to lead out a terminal from side of the end surface or side of the light-receiving surface. Thus, it is virtually not possible to perform tiling of a plurality of light-receiving devices in such a manner as to surround one light-receiving device (e.g., in a 3×3 matrix).

In the present embodiment, there is no region where light reception is not possible, as in such a case where FPC is led out from a top surface of the light-receiving device 1. Hence, it is possible to apply the light-receiving device 1 to a module in a large-sized light-receiving panel formed by means of tiling of a plurality of modules, for example.

### 2. Modification Example of First Embodiment

In the foregoing first embodiment, as illustrated in FIGS. 6 to 9, for example, the light-receiving device 1 may be provided with a plurality of photoelectric current extraction regions 14 in each of the light-receiving pixels Px. At this time, the photoelectric current extraction region 14, one of the plurality of photoelectric current extraction regions 14, is provided at the outer edge of the light-receiving pixel Px, and has a ring shape that surrounds the circuit region 15 on the first principal surface 10A. Further, one or a plurality of photoelectric current extraction regions 14 (hereinafter, referred to as a “second photoelectric current extraction region”), out of the plurality of photoelectric current extraction regions 14, other than the photoelectric current extraction region 14 provided at the outer edge of the light-receiving pixel Px are provided, for example, inside the region surrounded by the circuit region 15 on the first principal surface 10A, as illustrated in FIGS. 6 to 9.

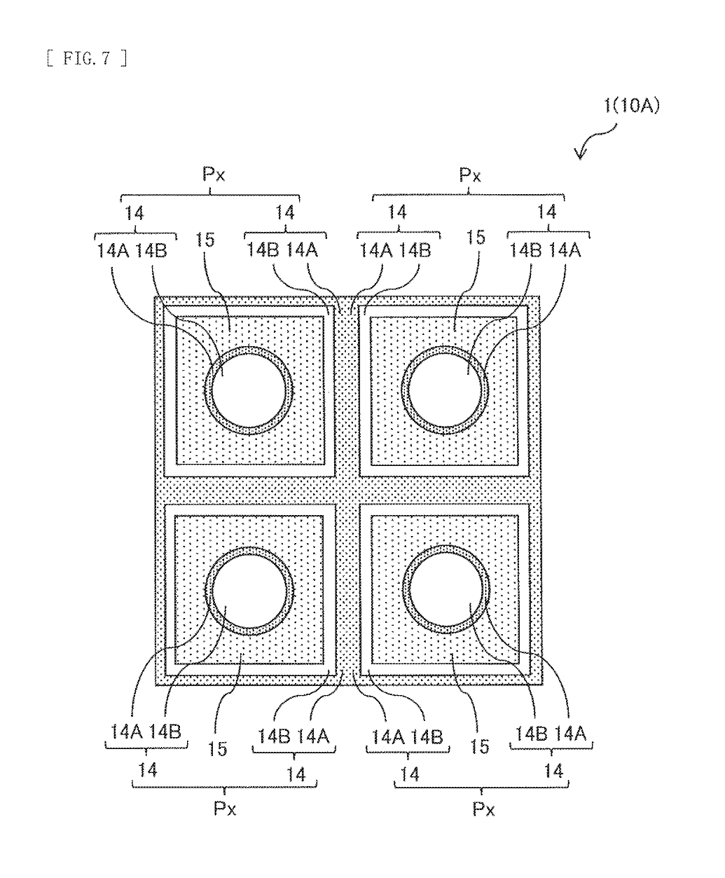

In the light-receiving device 1 of each of FIGS. 6 and 7, two photoelectric current extraction regions 14 are provided in each of the light-receiving pixels Px. At this time, the circuit region 15 has a ring shape on the first principal surface 10A, and the second photoelectric current extraction region is provided inside the region surrounded by the ring-shaped circuit region 15. In the second photoelectric current extraction region, the anode region 14A has a ring shape that is formed along an inner edge of the circuit region 15. In the second photoelectric current extraction region, the anode region 14A has a ring shape that surrounds the cathode region 14B on the first principal surface 10A. In the second photoelectric current extraction region, the cathode region 14B has an island shape that is in contact with the inner edge of the ring-shaped anode region 14A in the second photoelectric current extraction region. In the light-receiving device 1 of FIG. 6, the second photoelectric current extraction region has a square shape. Meanwhile, in the light-receiving device of FIG. 7, the second photoelectric current extraction region has a circular shape or an elliptical shape. In the light-receiving device 1 of each of FIGS. 6 and 7, the cathode region 14B is provided to be large. This helps the potential to be broadened, thus making it possible to form a backside structure without lowering in sensitivity.

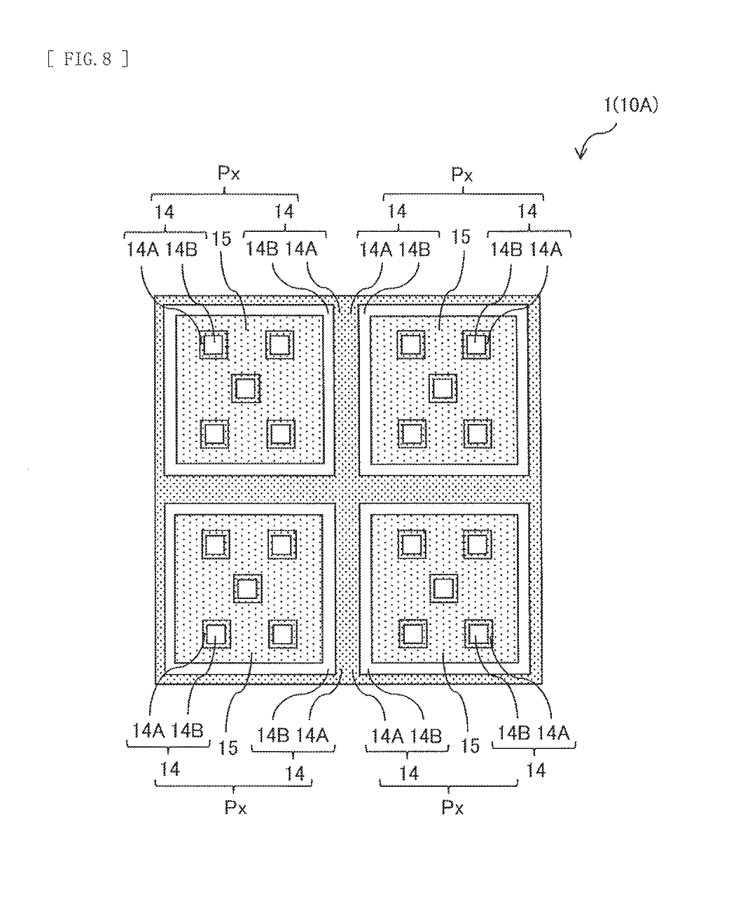

In the light-receiving device 1 of FIG. 8, six photoelectric current extraction regions 14 are provided in each of the light-receiving pixels Px. At this time, the circuit region 15 has a plurality of openings on the first principal surface 10A, and the second photoelectric current extraction region is provided inside each of the openings of the circuit region 15. In each second photoelectric current extraction region, the anode region 14A has a ring shape that is formed along the inner edge of the circuit region 15. In each second photoelectric current extraction region, the anode region 14A has a ring shape that surrounds the cathode region 14B on the first principal surface 10A. In each second photoelectric current extraction region, the cathode region 14B has an island shape that is in contact with the inner edge of the ring-shaped anode region 14A in the second photoelectric current extraction region. In the light-receiving device 1 of FIG. 8, the second photoelectric current extraction region has a square shape. It is to be noted that, in the light-receiving device 1 of FIG. 8, each second photoelectric current extraction region may have a circular shape or an elliptical shape. In the light-receiving device 1 of FIG. 8, the cathode region 14B is provided to be relatively large. Further, the circuit region 15 is also provided to be relatively large. Hence, it is possible to increase a degree of freedom of design.

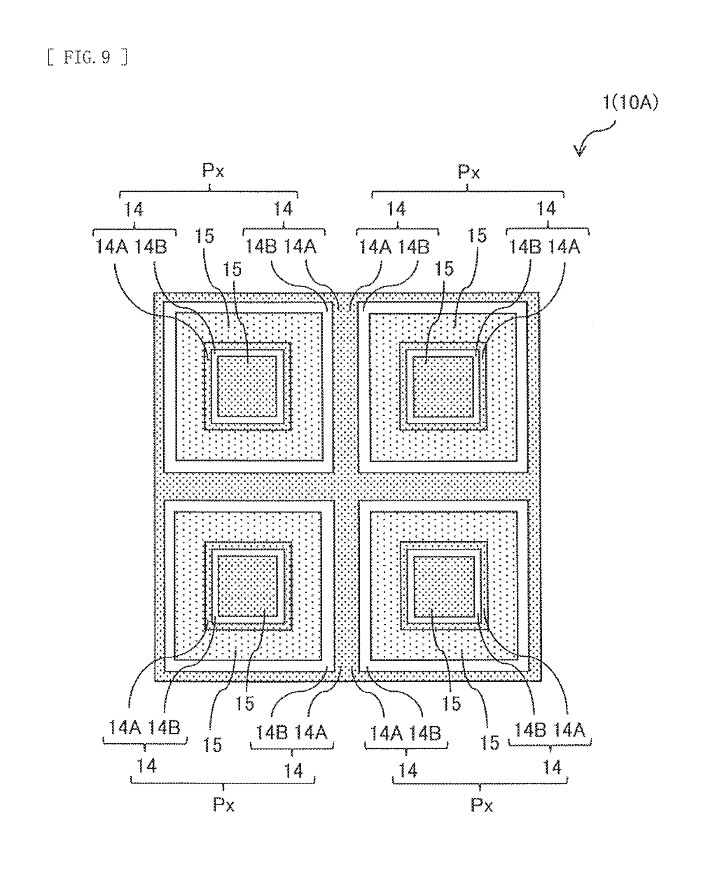

The light-receiving device 1 of FIG. 9 corresponds to the light-receiving device 1 of FIG. 6, in which the cathode region 14B in the second photoelectric current extraction region has a ring shape that is in contact with the inner edge of the ring-shaped anode region 14A in the second photoelectric current extraction region. In other words, in the light-receiving device of FIG. 9, the anode region 14A has a ring shape that is formed along the inner edge of the circuit region 15 in the second photoelectric current extraction region. In each second photoelectric current extraction region, the cathode region 14B has a ring shape that is in contact with the inner edge of the ring-shaped anode region 14A in the second photoelectric current extraction region. In the light-receiving device 1 of FIG. 9, the circuit region 15 is also provided in the region surrounded by the cathode region 14B in the second photoelectric current extraction region. In the light-receiving device 1 of FIG. 9, the cathode region 14B is provided to be relatively large. Further, the circuit region 15 is also provided to be relatively large. Hence, it is possible to increase a degree of freedom of design.

### 3. Second Embodiment

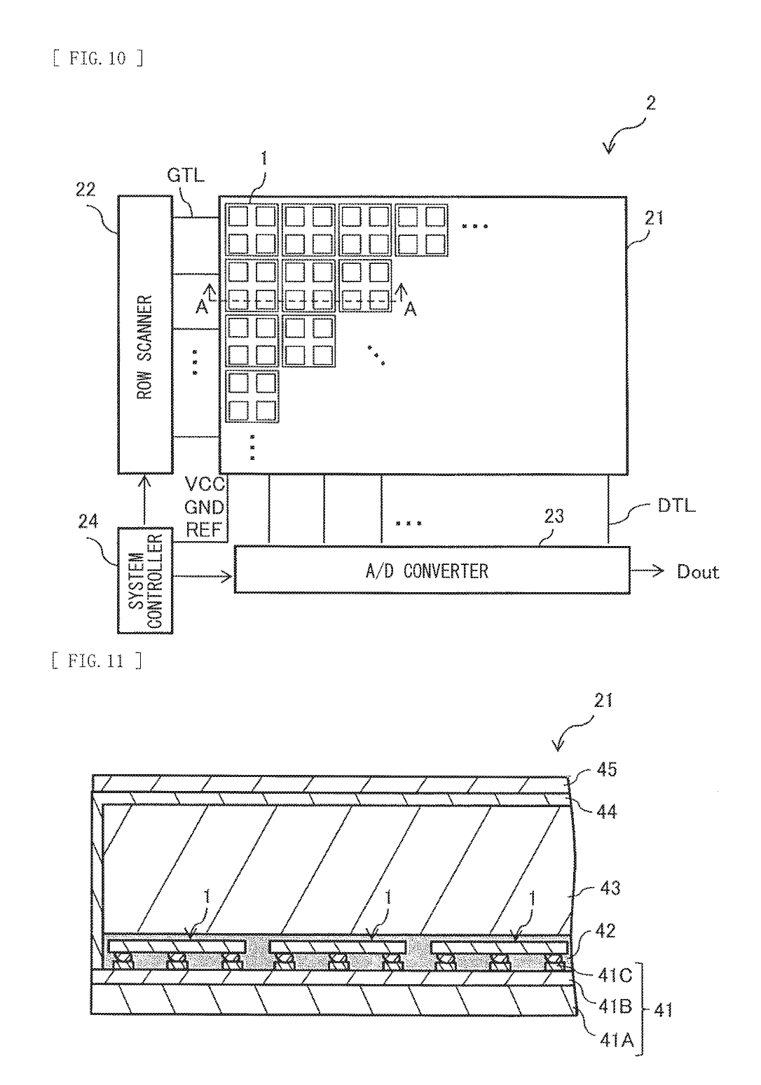

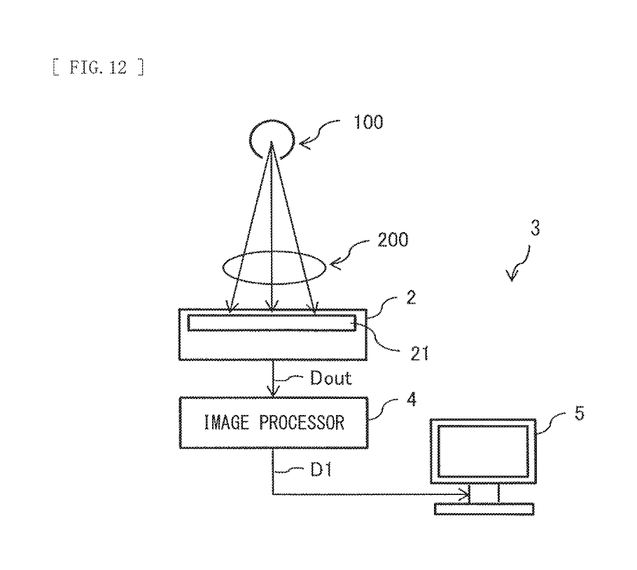

Description is given next of an imaging unit 2 according to a second embodiment. FIG. 10 illustrates an example of a schematic configuration of the imaging unit 2. The imaging unit 2 includes an imaging section 21 described later in which the above-described light-receiving device 1 is used. The imaging unit 2 is suitably used as an imaging unit for medical use and for any other non-destructive inspection such as baggage inspection. FIG. 11 illustrates an example of a cross-sectional configuration of the imaging section 21. The imaging unit 2 includes, for example, the imaging section 21 on a substrate, and includes a controller that controls the imaging section 21 in a peripheral region of the imaging section 21. The controller includes, for example, a row scanner n A/D converter 23, and a system controller 24. The controller corresponds to a specific example of a “controller” of the technology.

The imaging section 21 serves as an imaging area in the imaging unit 2. The imaging section 21 includes the plurality of light-receiving devices 1 that are arranged in matrix. Each of the light-receiving devices 1 outputs an electric signal (the output signal Vout) to be used for formation of a captured image to a signal line DTL (described later). The imaging section 21 includes, for example, a wiring substrate 41, the plurality of light-receiving devices 1, and a sensor protective layer 42. The light-receiving devices 1 are mounted in matrix on the wiring substrate 41 via the plurality of solder bumps 40. Each of the light-receiving devices 1 is disposed on the wiring substrate 41, with side of a bottom surface (the first principal surface 10A) being closer to the wiring substrate 41. At least one light-receiving device 1, of the plurality of light-receiving devices 1 mounted in matrix, is surrounded by other light-receiving devices 1 of the plurality of light-receiving devices 1. FIG. 11 exemplifies a state where each of the light-receiving devices 1 has a square top surface (the second principal surface 10B) and where the light-receiving devices 1, of the plurality of light-receiving devices 1, disposed at locations other than an outer edge of the imaging section 21 are arranged, with sides of the top surface (the second principal surface 10B) facing each other.

The wiring substrate 41 includes a support substrate 41A, a wiring layer 41B, and a plurality of pad electrodes 41C. The support substrate 41A is a substrate that supports the plurality of light-receiving devices 1, and is configured, for example, by a resin substrate, a glass substrate, or a semiconductor substrate (e.g., a silicon substrate) The support substrate 41A preferably has a linear expansion coefficient substantially equivalent to that of the semiconductor substrate 11. The wiring layer 41B is provided to electrically couple each of the light-receiving devices 1 and the controller of the imaging unit 2 to each other. The wiring layer 41B includes a plurality of signal lines DTL, and a plurality of gate lines GTL intersecting (e.g., orthogonal to) each of the signal lines DTL. The wiring layer 41B further includes a plurality of power supply voltage lines VCC each extending in a direction substantially parallel to each of the signal lines DTL, a plurality of ground lines GND each extending in a direction substantially parallel to each of the signal lines DTL, and a plurality of reference voltage lines REF each extending in a direction substantially parallel to each of the signal lines DTL. The plurality of light-receiving devices 1 are disposed at respective locations where the signal lines DTL and the gate lines GTL cross each other, for example.

Each of the signal lines DTL is a wiring line to read a signal electric charge from the light-receiving device 1. The gate line GTL is a wiring line to input, to the circuit region 15, a control signal that performs ON/OFF control of various switch elements included in the circuit region 15. A bias line BSL is a wiring line to determine, for example, a potential of the anode electrode 32 (anode potential) and a reference potential of the conversion circuit 15A. Each of the signal lines DTL extends in a perpendicular direction, for example.

The plurality of pad electrodes 41C are each provided to electrically couple each of the light-receiving devices 1 and the wiring layer 41B to each other, and also to regulate a position where each of the light-receiving device 1 is mounted on the wiring substrate 41. Each of the light-receiving devices 1 is coupled to the plurality of pad electrodes 41C via the plurality of solder bumps 40. Each of the light-receiving devices 1 is positioned with high accuracy at a predetermined position on the wiring substrate 41 by utilizing a self-alignment effect generated by surface tension of the plurality of solder bumps 40 having been fused in the manufacturing process.

The sensor protective layer 42 protects the plurality of light-receiving devices 1. The sensor protective layer 42 covers at least the end surface 10C of each of the light-receiving devices 1, and also covers the second principal surface 10B and the first principal surface 10A of each of the light-receiving devices 1, as necessary. The sensor protective layer 42 is formed integrally, for example, in such a manner as to cover the end surface 10C and the first principal surface 10A of each of the light-receiving devices 1. The respective top surfaces (the second principal surfaces 10B) of the light-receiving devices 1 are covered with the common sensor protective layer 42. At this time, the top surface of the sensor protective layer 42 is planar throughout an in-plane region of the imaging section 21 that is an imaging area of the imaging unit 2.

The sensor protective layer 42 is a halogen-based resin layer. The halogen-based resin layer is configured by a chlorine-based resin, for example. The sensor protective layer 42 preferably contains chlorine at 1,000 ppm or higher. The halogen-based resin layer to be used for the sensor protective layer 42 preferably has high light-transmissivity to light incident on the second principal surface 10B, and preferably has resistance to a radioactive ray. The sensor protective layer 42 is in direct contact with the end surface 10C of each of the light-receiving devices 1. The sensor protective layer 42 is formed by film-formation by means of a vapor deposition polymerization method, for example.

The imaging section 21 further includes a visible light conversion layer 43 on the side of the second principal surface 10B of each of the light-receiving devices 1 in terms of a positional relationship with each of the light-receiving devices 1. The visible light conversion layer 43 is provided on the sensor protective layer 42. The visible light conversion layer 43 performs wavelength conversion of a radioactive ray incident from the outside into a sensitivity region of each of the light-receiving devices 1. Specifically, the visible light conversion layer 43 converts the radioactive ray incident from the outside into visible light. The visible light conversion layer 43 is configured, for example, by a fluorescent material that converts a radioactive ray such as α-ray, β-ray, γ-ray, or X-ray into visible light. Examples of such a fluorescent material may include a substance containing cesium iodide (CsI) with thallium (TI) or sodium (Na) being added, and a substance containing sodium iodide (Nal) with thallium (TI) being added. Further, examples of the above-described fluorescent material may include a substance containing cesium bromide (CsBr) with europium (Eu) being added, and a substance containing cesium fluorobromide (CsBrF) with europium (Eu) being added.

As illustrated in FIG. 11, the visible light conversion layer 43 is disposed on a surface of the sensor protective layer 42 that covers the second principal surface 10B of each of the light-receiving devices 1. For example, the visible light conversion layer 43 is formed using the surface of the sensor protective layer 42 as a crystal-growing surface. For example, the visible light conversion layer 43 is formed by performing film-formation by means of a vacuum deposition method.

The imaging section 21 further includes a planarizing layer 44 that planarizes a top surface of the visible light conversion layer 43 while protecting the visible light conversion layer 43. The planarizing layer 44 is configured, for example, by a material that is common to or the same as that of the sensor protective layer 42. The planarizing layer 44 may be configured by a material different from that of the sensor protective layer 42

The imaging section 21 further includes a reflective layer 45 on a top surface of the planarizing layer 44. The reflective layer 45 has a role of returning, toward the light-receiving device 1, light outputted from the visible light conversion layer 43 in a direction opposite to the light-receiving device 1. The reflective layer 45 may be configured by a moisture-impermeable material that does not permeate moisture substantially. In such a case, it is possible for the reflective layer 45 to prevent ingress of moisture into the visible light conversion layer 43. The reflective layer 45 includes thin glass, for example. The reflective layer 45 may be omitted. A reflective structure to be provided on the visible light conversion layer 43 may have a configuration other than the reflective layer 45 as described above, and may be configured by a vapor-deposited film of Al, for example.

### [Operation]

Description is given next of an example of an operation of the imaging unit 2. When a radioactive ray is incident on a top surface of the imaging unit 2, the radioactive ray is converted into visible light in the visible light conversion layer 43. A reverse bias voltage is applied to each of the light-receiving devices 1 from a peripheral circuit of the imaging unit 2. When the converted visible light is incident on the second principal surface 10B of each of the light-receiving devices 1, a signal electric charge (photoelectric current) is generated that has an electric charge amount corresponding (proportional) to a light amount of the incident light. The generated signal electric charge (photoelectric current) is extracted inside each of the photoelectric current extraction region 14, is converted into the output signal Vout by the circuit region 15, and is led out to the signal line DTL.

### [Effects]

Description is given next of effects of the imaging unit 2. In the imaging unit 2, the plurality of light-receiving devices 1 are used for the imaging section 21. This makes it possible to achieve the imaging unit 2 having high sensitivity while suppressing increase in manufacturing costs.

In the present embodiment, the provision of the photoelectric current extraction region 14 on the first principal surface 10A of the light-receiving device 1 allows for soldering mounting, thus making it possible to narrow a gap between the light-receiving devices 1 that are adjacent to each other. This makes it possible to lay the plurality of light-receiving devices 1 on a wiring substrate or the like almost without any clearance. For example, in a case of a so-called surface-type having a cathode region as a light-receiving surface, it is necessary to lead out FPC from the side of the light-receiving surface. Thus, it is virtually not possible to perform tiling of a plurality of light-receiving devices in such a manner as to surround one light-receiving device (e.g., in a 3×3 matrix). Further, in the present embodiment, there is no region where light reception is not possible, as in such a case where FPC is led out from the top surface of the light-receiving device 1. Hence, it is possible to apply the light-receiving device 1 to a module in a large-sized light-receiving panel formed by means of tiling of a plurality of modules, such as the imaging unit 2.

In the present embodiment, the sensor protective layer 42 is a halogen-based resin layer, and is configured by a chlorine-based resin, for example. Further, the sensor protective layer 42 is in direct contact with the end surface 10C of each of the light-receiving devices 1.

As described above, the end surface 10C is formed by cutting by means of dicing, dry etching, or the like. Accordingly, the end surface 10C has more or less collapse of a crystal structure. This collapse of the crystal structure makes carriers (i.e. a dark current) likely to be generated. The sensor protective layer 42 that is a halogen-based resin layer being in direct contact with the end surface 10C of each of the light-receiving devices 1 makes it possible to suppress generation of carriers at the end surface 10C. As a result, it becomes possible to improve the sensitivity with a simple configuration. Hence, it is possible to suppress increase in manufacturing costs while improving the sensitivity. Further, in a case where the sensor protective layer 42 contains chlorin: at 1,000 ppm or higher, it is possible to achieve high X-ray resistance.

In the present embodiment, in a case where the sensor protective layer 42 is formed integrally in such a manner as to cover the end surface 10C and the first principal surface 10A of each of the light-receiving devices 1, it is possible to easily form the visible light conversion layer 43 to have high quality on the sensor protective layer 42. Hence, it is possible to suppress increase in manufacturing costs while improving the sensitivity.

### 4. Third Embodiment

Description is given next of an imaging system 3 according to a fourth embodiment. FIG. 13 illustrates an example of a schematic configuration of an imaging system 3. The imaging system 3 includes the imaging unit 2 in which the plurality of light-receiving device 1 are used for the imaging section 21. The imaging system 3 includes, for example, the imaging unit 2, an image processor 4, and a display unit 5. It is to be noted that the display unit 5 may be omitted as necessary.

The image processor 4 implements a predetermined processing on image data Dout obtained in the imaging unit 2. Specifically, the image processor 4 generates a display signal D1 by implementing the predetermined image processing on the image data Dout. The display unit 5 displays an image on the basis of the display signal D1 obtained by the image processor 4.

In the present embodiment, out of a radioactive ray irradiated from a radiation source 100 toward an analyte 200, a component having been transmitted through the analyte 200 is detected by the imaging unit 2. The data Dout obtained through detection performed by the imaging unit 2 is subjected to the predetermined processing by the image processor 4. As a result of having been subjected to the predetermined processing, the obtained display signal D1 is outputted to the display unit 5, and an image corresponding to the display signal D1 is displayed on a monitor screen of the display unit 5.

In this manner, in the present embodiment, the plurality of light-receiving devices 1 are used in the imaging unit 2. Hence, it is possible to obtain a high-sensitivity image.

### 5. Modification Example of Third Embodiment

In the foregoing third embodiment, the imaging system 3 may further include a molding apparatus (unillustrated) that molds a three-dimensional object on the basis of an imaging signal (3D computer-aided design (CAD) signal) having been processed in the image processor 4. The molding apparatus is a 3D printer, for example. The image processor 4 generates the 3DCAD signal by implementing a predetermined image processing on the imaging signal Dout.

In the present modification example, the plurality of light-receiving devices 1 are used in the imaging unit 2. Hence, it is possible to obtain a high-accuracy three-dimensional object.

Although the present disclosure has been described above referring to the embodiments and the modification examples thereof the present disclosure is not limited to the foregoing embodiments, etc., and may be modified in a variety of ways.

For example, in the foregoing respective embodiments and modification examples thereof, the semiconductor may have an electroconductive type that is opposite to the above-described electroconductive type. For example, in a case where the electroconductive type of the semiconductor is described as a p-type, the p-type may be read as n-type. Further, in a case where the electroconductive type of the semiconductor is described as an n-type, the n-type may be read as p-type.

Further, for example, in the foregoing respective embodiments and modification examples thereof, a pin structure may be adopted instead of the pn structure.

It is to be noted that the effects described herein are merely illustrative. The effects of the present disclosure are not limited to those described in the present specification. The present disclosure may have effects other than those described in the present specification.

Further, for example, the present disclosure may have the following configurations.

(1)

A light-receiving device including:

a pixel region provided on a first principal surface of a semiconductor layer that includes the first principal surface, a second principal surface, and an end surface, and including a plurality of light-receiving pixels each receiving light incident from side of the second principal surface, the second principal surface facing the first principal surface; and

a low-impurity region provided throughout a gap between the second principal surface and the pixel region, and having a relatively lower impurity concentration than the pixel region,

the light-receiving pixels each including
one or a plurality of photoelectric current extraction regions each including, on the first principal surface, an anode region and a cathode region, and
a circuit region that is electrically coupled to each of the cathode regions and is electrically separated from the impurity region.
   (2)

The light-receiving device according to (1), in which the pixel region includes, between the impurity region and the circuit region, a separation region that electrically separates the impurity region and the circuit region from each other.

(3)

The light-receiving device according to (2), in hick the separation region is configured by an impurity region that contains, at a higher concentration than the impurity region, impurities of a same electroconductive type as the impurity region.

(4)

The light-receiving device according to any one of (1) to (3), in which a first photoelectric current extraction region that is one of the one or the plurality of photoelectric current extraction regions is provided at an outer edge of the light-receiving pixel, and has a ring shape that surrounds the circuit region on the first principal surface.

(5)

The light-receiving device according to (4), in which, in a case where the light-receiving pixels each include the plurality of photoelectric current extraction regions, one or a plurality of second photoelectric current extraction regions, out of the plurality of photoelectric current extraction regions and other than the first photoelectric current extraction region, are provided inside a region surrounded by the circuit region on the first principal surface.

(6)

The light-receiving device according to (5), in which, in each of the second photoelectric current extraction regions, the cathode region has an island shape, and the anode region has a ring shape that surrounds the cathode region on the first principal surface.

(7)

The light-receiving device according to (5), in which, in each of the second photoelectric current extraction regions, the cathode region and the anode region both have a ring shape that surrounds a portion of the circuit region on the first principal surface.

(8)

The light-receiving device according to one of (1) to (7), in which each of the circuit regions includes, out of a conversion circuit and a buffer circuit, at least the conversion circuit, the conversion circuit converting a photoelectric current outputted from the photoelectric current extraction region, the buffer circuit being coupled to output side of the conversion circuit.

(9)

The light-receiving device according to any one of (1) to (8), including:

a wiring layer provided on side of the first principal surface, and including a plurality of wiring lines electrically coupled to each of the light-receiving pixels; and

a plurality of solder bumps provided, on a surface of the wiring layer, for the respective wiring lines.

(10)

The light-receiving device according to any one of (1) to (9), further including a halogen-based resin layer that is in direct contact with the entire end surface.

(11)

The light-receiving device according to (10), in which he resin layer is configured by a chlorine-based resin.

(12)

An imaging unit including:

a wiring substrate; and

a plurality of light-receiving devices mounted in matrix on the wiring substrate,

the plurality of light-receiving devices each including

a pixel region provided on a first principal surface of a semiconductor layer that includes the first principal surface, a second principal surface, and an end surface, and including a plurality of light-receiving pixels each receiving light incident from side of the second principal surface, the first principal surface being closer to the wiring substrate, the second principal surface facing the first principal surface, and

a low-impurity region provided throughout a gap between the second principal surface and the pixel region, and having a relatively low impurity concentration, the light-receiving pixels each including
one or a plurality of photoelectric current extraction regions each including, on the first principal surface, an anode region and a cathode region, and
a circuit region that is electrically coupled to each of the cathode regions and is electrically separated from the impurity region.
   (13)

The imaging unit according to (12), in which

the light-receiving devices each include_{;}
a wiring layer provided on side of the first principal surface, and including a plurality of wiring lines electrically coupled to each of the light-receiving pixels, and
a plurality of solder bumps provided on a surface of the wiring layer, and each being electrically coupled to the plurality of wiring lines, and.

the light-receiving devices are each mounted on the wiring substrate via the plurality of solder bumps.

(14)

The imaging unit according to (13), in which at least one of the plurality of light-receiving devices is surrounded by other light-receiving devices of the plurality of light-receiving devices.

(15)

The imaging unit according to any one of (12) to (14), in which the light-receiving devices each further include a halogen-based resin layer that is in direct contact with the entire end surface.

(16)

The imaging unit according to (15), in which the resin layer of each of the light-receiving devices is formed integrally in such a manner as to cover the end surface and the top surface of each of the light-receiving devices.

(17)

The imaging unit according to (16), in which the light-receiving devices each include, on the resin layer, a visible light conversion layer that converts a radioactive ray into visible light.

(18)

An electronic apparatus including:

an imaging unit; and

a processing unit that processes image data obtained by the imaging unit,

the imaging unit including

a wiring substrate, and

a plurality of light-receiving devices mounted in matrix on the wiring substrate,

the plurality of light-receiving devices each including

a pixel region provided on a first principal surface of a semiconductor layer that includes the first principal surface, a second principal surface, and an end surface, and including a plurality of light-receiving pixels each receiving light incident from side of the second principal surface, the first principal surface being closer to the wiring substrate, the second principal surface facing the first principal surface, and

a low-impurity region provided throughout a gap between the second principal surface and the pixel region, and having a relatively low impurity concentration,

the light-receiving pixels each including
one or a plurality of photoelectric current extraction regions each including, on the first principal surface, an anode region and a cathode region, and
   a circuit region that is electrically coupled to each of the cathode regions and is electrically separated from the impurity region.

This application claims the benefit of Japanese Priority Patent Application JP2016-067646 filed with the Japan Patent Office on Mar. 30, 2016, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A light-receiving device comprising:
a pixel region provided on a first principal surface of a semiconductor layer that includes the first principal surface, a second principal surface, and an end surface, and including a plurality of light-receiving pixels each receiving light incident from side of the second principal surface, the second principal surface facing the first principal surface; and
a low-impurity region provided throughout a gap between the second principal surface and the pixel region, and having a relatively lower impurity concentration than the pixel region,
the light-receiving pixels each including
one or a plurality of photoelectric current extraction regions each including, on the first principal surface, an anode region and a cathode region, and
a circuit region that is electrically coupled to each of the cathode regions and is electrically separated from the impurity region.

2. The light-receiving device according to claim 1, wherein the pixel region includes, between the impurity region and the circuit region, a separation region that electrically separates the impurity region and the circuit region from each other.

3. The light-receiving device according to claim 2, wherein the separation region is configured by an impurity region that contains, at a higher concentration than the impurity region, impurities of a same electroconductive type as the impurity region.

4. The light-receiving device according to claim 1, wherein a first photoelectric current extraction region that is one of the one or the plurality of photoelectric current extraction regions is provided at an outer edge of the light-receiving pixel, and has a ring shape that surrounds the circuit region on the first principal surface.

5. The light-receiving device according to claim 4, wherein, in a case where the light-receiving pixels each include the plurality of photoelectric current extraction regions,
one or a plurality of second photoelectric current extraction regions, out of the plurality of photoelectric current extraction regions and other than the first photoelectric current extraction region, are provided inside a region surrounded by the circuit region on the first principal surface.

6. The light-receiving device according to claim 5, wherein, in each of the second photoelectric current extraction regions, the cathode region has an island shape, and the anode region has a ring shape that surrounds the cathode region on the first principal surface.

7. The light-receiving device according to claim 5, wherein, in each of the second photoelectric current extraction regions, the cathode region and the anode region both have a ring shape that surrounds a portion of the circuit region on the first principal surface.

8. The light-receiving device according to claim 1, wherein each of the circuit regions includes, out of a conversion circuit and a buffer circuit, at least the conversion circuit, the conversion circuit converting a photoelectric current outputted from the photoelectric current extraction region, the buffer circuit being coupled to output side of the conversion circuit.

9. The light-receiving device according to claim 8, comprising:
a wiring layer provided on side of the first principal surface, and including a plurality of wiring lines electrically coupled to each of the light-receiving pixels; and
a plurality of solder bumps provided, on a surface of the wiring layer, for the respective wiring lines.

10. The light-receiving device according to claim 1, further comprising a halogen-based resin layer that is in direct contact with the entire end surface.

11. The light-receiving device according to claim 10, wherein the resin layer is configured by a chlorine-based resin.

12. An imaging unit comprising:
a wiring substrate; and
a plurality of light-receiving devices mounted in matrix on the wiring substrate,
the plurality of light-receiving devices each including
a pixel region provided on a first principal surface of a semiconductor layer that includes the first principal surface, a second principal surface, and an end surface, and including a plurality of light-receiving pixels each receiving light incident from side of the second principal surface, the first principal surface being closer to the wiring substrate, the second principal surface facing the first principal surface, and
a low-impurity region provided throughout a gap between the second principal surface and the pixel region, and having a relatively low impurity concentration,
the light-receiving pixels each including
one or a plurality of photoelectric current extraction regions each including, on the first principal surface, an anode region and a cathode region, and
a circuit region that is electrically coupled to each of the cathode regions and is electrically separated from the impurity region.

13. The imaging unit according to claim 12, wherein
the light-receiving devices each include,
a wiring layer provided on side of the first principal surface, and including a plurality of wiring lines electrically coupled to each of the light-receiving pixels, and
a plurality of solder bumps provided on a surface of the wiring layer, and each being electrically coupled to the plurality of wiring lines, and
the light-receiving devices are each mounted on the wiring substrate via the plurality of solder bumps.

14. The imaging unit according to claim 13, wherein at least one of the plurality of light-receiving devices is surrounded by other light-receiving devices of the plurality of light-receiving devices.

15. The imaging unit according to claim 12, wherein the light-receiving devices each further include a halogen-based resin layer that is in direct contact with the entire end surface.

16. The imaging unit according to claim 15, wherein the resin layer of each of the light-receiving devices is formed integrally in such a manner as to cover the end surface and the top surface of each of the light-receiving devices.

17. The imaging unit according to claim 16, wherein the light-receiving devices each include, on the resin layer, a visible light conversion layer that converts a radioactive ray into visible light.

18. An electronic apparatus comprising:
an imaging unit; and
a processing unit that processes image data obtained by the imaging unit,
the imaging unit including
a wiring substrate, and
a plurality of light-receiving devices mounted in matrix on the wiring substrate,
the plurality of light-receiving devices each including
a pixel region provided on a first principal surface of a semiconductor layer that includes the first principal surface, a second principal surface, and an end surface, and including a plurality of light-receiving pixels each receiving light incident from side of the second principal surface, the first principal surface being closer to the wiring substrate, the second principal surface facing the first principal surface, and
a low-impurity region provided throughout a gap between the second principal surface and the pixel region, and having a relatively low impurity concentration,
the light-receiving pixels each including
one or a plurality of photoelectric current extraction regions each including, on the first principal surface, an anode region and a cathode region, and
a circuit region that is electrically coupled to each of the cathode regions and is electrically separated from the impurity region.
